(19) United States
(12) Patent Application Publication
(10) Pub. No.: US 2011/0180139 A1
(43) Pub. Date: Jul. 28, 2011

(54) PASTE COMPOSITION FOR ELECTRODE AND PHOTOVOLTAIC CELL

(75) Inventors: SHUUICHIROU ADACHI, Tsukuba-shi (JP); Masato Yoshida, Tsukuba-shi (JP); Takeshi Nojiri, Tsukuba-shi (JP); Mitsunori Iwamuro, Tsukuba-shi (JP); Keiko Kizawa, Tsukuba-shi (JP); Takuya Aoyagi, Hitachi-shi (JP); Hiroki Yamamoto, Hitachi-shi (JP); Takashi Naito, Hitachi-shi (JP); Takahiko Kato, Hitachi-shi (JP)

(73) Assignee: HITACHI CHEMICAL COMPANY, LTD.

(21) Appl. No.: 13/013,230

(22) Filed: Jan. 25, 2011

Related U.S. Application Data
(60) Provisional application No. 61/298,137, filed on Jan. 25, 2010.

(51) Int. Cl. H01L 31/0224; H01B 1/22

(52) U.S. Cl. 136/256; 252/514

(57) ABSTRACT

The paste composition for an electrode of the first aspect of the present invention includes silver alloy particles, glass particles, a resin, and a solvent. The paste composition for an electrode of the second aspect of the present invention includes copper particles, silver or silver alloy particles, glass particles containing P₂O₅ and V₂O₅, a resin, and a solvent, in which the content of the copper particles to the silver or silver alloy particles is from 9% by mass to 88% by mass. Further, the cell of a photovoltaic cell of the present invention has an electrode formed by using the paste composition for an electrode.

### CROSS-REFERENCE TO RELATED APPLICATIONS

This application claims priority under 35 U.S.C. 119(e) to Provisional U.S. Patent Application No. 61/298,137, filed Jan. 25, 2010, the disclosure of which is incorporated by reference herein.

### BACKGROUND OF THE INVENTION

1. Field of the Invention

The present invention relates to a paste composition for an electrode and a photovoltaic cell.

2. Description of the Related Art

Generally, a photovoltaic cell is provided with a surface electrode, in which the wiring resistance or contact resistance of the surface electrode is related to a voltage loss associated with conversion efficiency, and further, the wiring width or shape has an influence on the amount of the incident sunlight (see, for example, “Sunlight Power Generation, Newest Technology and Systems”, edited by Yoshihiro Hamakawa, CMC Books, 2001, p. 26-27).

The surface electrode of a photovoltaic cell is usually formed in the following manner. That is, a conductive composition is applied onto an n-type semiconductor layer, which is formed by thermally diffusing phosphorous and the like on the light-receiving surface side of a p-type silicon substrate at a high temperature, by screen printing or the like, and sintered at a high temperature of 800 to 900° C., thereby forming a surface electrode. This conductive composition for forming the surface electrode includes conductive metal powders, glass particles, various additives, and the like.

As the conductive metal powders, silver powders are generally used, but the use of metal powders other than silver powders is being investigated for various reasons. For example, a conductive composition capable of forming an electrode for a photovoltaic cell, including silver and aluminum, is disclosed (see, for example, Japanese Patent Application Laid-Open (JP-A) No. 2006-313744). In addition, a composition for forming an electrode, including metal nanoparticles including silver and metal particles other than silver, is disclosed (see, for example, JP-A No. 2008-226816 2).

### SUMMARY OF THE INVENTION

Silver, which is generally used to form an electrode, is a noble metal and, in view of problems regarding resources and also from the viewpoint that the ore is expensive, proposals for a paste material which replaces the silver-containing conductive composition (silver-containing paste) are desirable.

Therefore, it is a first object according to the present invention to provide a paste composition for an electrode, which is capable of forming an electrode with inhibition of the increase in the resistivity as well as reduction in the amount of silver to be used, and a photovoltaic cell having an electrode formed by using the paste composition for an electrode.

Furthermore, in consideration of the effect on the environment, it is preferable to use lead-free glass which does not substantially contain lead as the glass particles included in a conductive composition. The lead-free glass preferably includes glass containing diphosphorus pentoxide (phosphoric acid glass, P₂O₅-based glass), and more preferably glass further containing divanadium pentoxide in addition to diphosphorus pentoxide (P₂O₅—V₂O₅-based glass), from the viewpoint of low contact resistivity. By further including divanadium pentoxide, the oxidation resistance is further improved, and the resistivity of the electrode is further reduced. It is thought that this is why, for example, further including divanadium pentoxide leads to a decrease in the softening point of glass.

However, it became apparent that V₂O₅ (divanadium pentoxide) reacts with silver which is contained as a conductive metal powder, and thus, the resistivity of the electrode to be formed increases.

Therefore, it is a second object of the present invention to provide a paste composition for an electrode capable of forming an electrode having a low resistivity even with the use of lead-free glass, and a photovoltaic cell having an electrode formed by using the paste composition for an electrode.

A first embodiment of the present invention is a paste composition for an electrode including silver alloy particles, glass particles, a resin, and a solvent. This paste composition for an electrode preferably further includes silver particles. Further, the glass particles are preferably glass containing P₂O₅ and V₂O₅. Also, in the paste composition for an electrode, the total content of the silver alloy particles and the silver particles is from 70% by mass to 94% by mass, a content of the glass particles is from 0.1% by mass to 10% by mass, and a total content of the solvent and the resin is from 3% by mass to 30% by mass.

A second embodiment of the present invention is a paste composition for an electrode including copper particles, silver or silver alloy particles, glass particles containing P₂O₅, and V₂O₅, a resin, and a solvent, in which the content of the copper particles with respect to the silver or silver alloy particles is from 9% by mass to 88% by mass.

A third embodiment of the present invention is a photovoltaic cell having an electrode, in which the electrode is formed by applying the paste composition for an electrode to a silicon substrate, and sintering the paste composition.

According to the present invention, there is provided a paste composition for an electrode, which is capable of forming an electrode that inhibits an increase in resistivity while reducing the amount of silver to be used, and a photovoltaic cell having an electrode formed by using the paste composition for an electrode.

In addition, according to the present invention, there is provided a paste composition for an electrode, which is capable of forming an electrode having a low resistivity even with the use of a lead-free glass, and a photovoltaic cell having an electrode formed by using the paste composition for an electrode.

### BRIEF DESCRIPTION OF THE DRAWINGS

FIG. 1 is a cross-sectional view of the photovoltaic cell according to the present invention.

FIG. 2 is a plane view showing the light-receiving surface side of the photovoltaic cell according to the present invention.

FIG. 3 is a plane view showing the back surface side of the photovoltaic cell according to the present invention.

FIG. 4A is a perspective view showing the AA cross-sectional constitution of the cell back contact-type photovoltaic cell according to the present invention.

FIG. 4B is a plane view showing an electrode structure of the back surface side of the cell back contact-type photovoltaic cell according to the present invention.

### DETAILED DESCRIPTION OF THE INVENTION

Hereinafter, the embodiments of the present invention will be described in detail. Furthermore, in the present specification, “to” denotes a range including each of the minimum value and the maximum value of the values described before and after the reference.

### <Paste Composition for Electrode of First Embodiment>

The paste composition for an electrode of the first embodiment according to the present invention includes silver alloy particles, glass particles, a resin, and a solvent. By including the silver alloy particles, it becomes possible to form an electrode in which an increase in resistivity is inhibited and the amount of silver to be used is reduced.

Hereinafter, each of the components constituting the paste composition for an electrode of the first embodiment will be described in detail.

### (Silver Alloy Particles)

The silver alloy particle according to the present invention is an alloy including at least silver, and examples of other components include Cu, P, Zn, Mn, Mg, V, Sn, Zr, W, Mo, Ti, Co, Sb and Ni, which can be respectively used singly or in combination of two or more kinds thereof.

Furthermore, silver may further contain other atoms which are inevitably incorporated. Examples of other atoms which are inevitably incorporated include Sb, Si, K, Na, Li, Ba, Sr, Ca, Mg, Be, Zn, Pb, Cd, Tl, V, Sn, Al, Zr, W, Mo, Ti, Co, Ni, and Au.

Preferable combinations of silver alloys include Ag—Cu, Ag—Cu—P, Ag—Cu—Mn, Ag—Cu—Zn, Ag—Cu—Mg, Ag—Cu—V, Ag—Cu—Sn, Ag—Cu—Ti, Ag—Cu—Co, Ag—Cu—Sb, Ag—Cu—P—Mn, Ag—Cu—P—Zn, Ag—Cu—P—Mg, Ag—Cu—P—V, Ag—Cu—P—Sn, Ag—Cu—P—Ti, Ag—Cu—P—Co, Ag—Cu—P—Sb, and the like.

For example, in the case of an Ag—Cu alloy, it is preferable that the content of Ag be from 12 to 91% by mass, and the content of Cu be from 9 to 88% by mass, and it is more preferable that the content of Ag be from 23 to 83% by mass and the content of Cu be from 17 to 77% by mass.

Further, in the case of an Ag—Cu—P alloy, it is preferable that the content of Ag be from 12 to 91% by mass, the content of Cu be from 1 to 87.99% by mass, and the content of P be from 0.01 to 8% by mass, and it is more preferable that the content of Ag be from 23 to 83% by mass, the content of Cu be from 9.5 to 76% by mass, and the content of P be from 1 to 7.5% by mass.

The content of silver in the silver alloy particles in the present invention is preferably from 12 to 91% by mass, and more preferably from 23 to 83% by mass, based on the total mass of the silver alloy particles.

When the content is in the above range, an effect of reduction in the amount of silver to be used is obtained, and the increase in the low efficiency of the electrode is inhibited.

The silver alloys may be used singly or in combination of two or more kinds thereof.

The particle diameter of the silver alloy particles is not particularly limited, and it is preferably from 0.4 to 10 μm, and more preferably from 1 to 7 μm in terms of a particle diameter when the cumulative mass is 50% (hereinafter abbreviated as “D50%” in some cases). When the particle diameter is 0.4 μm or more, the oxidation resistance is improved more effectively. Further, when the particle diameter is 10 μm or less, the contact area at which the silver alloy particles contact each other in the electrode increases, and thus, resistivity is reduced more effectively.

In addition, the shape of the silver alloy particle is not particularly limited, and it may be any one of an approximately spherical shape, a flat shape, a block shape, a plate shape, a scale-like shape, and the like. From the viewpoint of oxidation resistance and low resistivity, it is preferably an approximately spherical shape, a flat shape, or a plate shape.

The silver alloy can be prepared by a generally used method. Further, the silver alloy particles can be prepared by a general method for preparing metal powders using a silver alloy that is prepared so as to give a desired silver content with a general method, for example, a water atomization method. The water atomization method is described in the Handbook of Metal (Maruzen CO., LTD. Publishing Dept.) or the like.

Specifically, for example, a desired silver alloy particle can be prepared by dissolving a silver alloy, forming a powder by nozzle spray, drying the obtained powders, and classifying them. Further, a silver alloy particle having a desired particle diameter can be prepared by appropriately selecting the classification condition.

The content of the silver alloy particles, or the total content of the silver alloy particles and the silver particles, when including the silver particles as described later, included in the paste composition for an electrode according to the present invention may be, for example, from 70 to 94% by mass. From the viewpoint of oxidation resistance and low resistivity, it is preferably from 72 to 90% by mass, and more preferably from 74 to 88% by mass.

When the total content of the silver alloy particles and the silver particles is 70% by mass or more, a suitable viscosity upon applying the paste composition for an electrode can be easily attained. Also, when the total content of the silver alloy particles and the silver particles is 94% by mass or less, the occurrence of abrasion upon providing the paste composition for an electrode can be inhibited more effectively.

Moreover, in the present invention, from the viewpoint of the oxidation resistance and the low resistivity of the electrode, the content of the silver alloy particles having a silver content of 12 to 91% by mass, or the total content of the silver particles and silver alloy particles having a silver content of 12 to 91% by mass when including the silver particles as described later, is preferably from 70 to 94% by mass, based on the paste composition for an electrode. Furthermore, the content of the silver alloy particles having a silver content of 23 to 83% by mass, or the total content of the silver particles and silver alloy particles having a silver content of 23 to 83% by mass when including the silver particles as described later, is preferably from 74 to 88% by mass, based on the paste composition for an electrode.

In the present invention, conductive particles other than the silver alloy particles may be used in combination therewith. Examples of the conductive particles include the silver particles as described later.

### (Glass Particles)

The paste composition for an electrode of the first embodiment according to the present invention includes at least one kind of glass particle. By incorporating glass particles in the paste composition for an electrode, a silicon nitride film which is an anti-reflection film is removed by a so-called fire-through at an electrode-forming temperature, and an ohmic contact between the electrode and the silicon substrate is formed.

As the glass particles, any known glass particles in the related art may be used without a particular limitation, provided the glass particles are softened or melted at an electrode-forming temperature to contact with the silicon nitride, thereby oxidizing the silicon nitride and then incorporating the oxidized silicon dioxide thereof.

In the present invention, the glass particles preferably contain glass having a glass softening point of 600° C. or lower and a crystallization starting temperature of higher than 600° C., from the viewpoint of the oxidation resistance and the low resistivity of the electrode. Further, the glass softening point is more preferably 450° C. or lower, from the viewpoint of the low resistivity of the electrode.

Moreover, the glass softening point is measured by a general method using a ThermoMechanical Analyzer (TMA), and the crystallization starting temperature is measured by a general method using a ThermoGravimetry/Differential Thermal Analyzer (TG/DTA).

The glass particles generally included in the paste composition for an electrode may be constituted with lead-containing glass, at which silicon dioxide is efficiently captured. Examples of such the lead-containing glass include those described in Japanese Patent 03050064 and the like, which can be preferably used in the present invention.

Furthermore, in the present invention, in consideration of an effect on the environment, it is preferable to use lead-free glass which does not substantially contain lead. Examples of the lead-free glass include lead-free glass described in Paragraphs 0024 to 0025 of JP-A No. 2006-313744, and lead-free glass described in JP-A No. 2009-188281 and the like, and it is also preferable to appropriately select one from the lead-free glass as above for the present invention.

Moreover, the glass particles preferably include glass containing diphosphorus pentoxide (phosphoric acid glass, P₂O₅-based glass), and more preferably glass further containing divanadium pentoxide in addition to diphosphorus pentoxide (P₂O₅—V₂O₅-based glass), from the viewpoint of low contact resistivity. By further including divanadium pentoxide, the oxidation resistance is further improved, and the resistivity of the electrode is further reduced. It is thought that this is caused by, for example, decrease in the softening point of glass as a result of further including divanadium pentoxide.

When the glass particles include diphosphorus pentoxide-divanadium pentoxide-based glass (P₂O₅—V₂O₅-based glass), the content of divanadium pentoxide is preferably 1% by mass or more based on the total mass of glass, and more preferably from 1 to 70% by mass.

Moreover, the diphosphorus pentoxide-divanadium pentoxide-based glass can further include other components, if necessary. Examples of other components include barium oxide (BaO), manganese dioxide (MnO₂), sodium oxide (Na₂O), potassium oxide (K₂O), zirconium dioxide (ZrO₂), tungsten trioxide (WO₃), tellurium oxide (TeO), molybdenum oxide (MoO₃), and antimony oxide (Sb₂O₃). By further including other components, silicon dioxide derived from the silicon nitride can be more efficiently incorporated. Further, the softening or melting temperature can be further reduced. In addition, the reaction with the copper-containing particles or silver particles that are added, if necessary, can be inhibited.

Furthermore, when the glass particles include divanadium pentoxide, silver reacts with vanadium. However, the silver alloy instead of silver inhibits the reaction, whereby the volume resistance of the electrode is further reduced. Also, when a silicon substrate for forming an electrode is treated by an aqueous hydrofluoric acid solution for the purpose of improving the energy conversion efficiency of a photovoltaic cell, using silver alloy leads to improvement in the resistance of the electrode material against the aqueous hydrofluoric acid solution (this property means that the electrode material does not peel from the silicon substrate due to the aqueous hydrofluoric acid solution).

The content of the glass particles is preferably from 0.1 to 10% by mass, more preferably from 0.5 to 8% by mass, and even more preferably from 1 to 7% by mass, based on the total mass of the paste composition for an electrode of the first embodiment. By including the glass particles at the content in this range, the oxidation resistance, the low resistivity of the electrode, and the low contact resistance are attained more effectively.

In the present invention, it is preferable to contain glass particles including P₂O₅—V₂O₅-based glass in an amount of from 0.1% by mass to 10% by mass based on the total mass of the paste composition for an electrode of the first embodiment as the glass particles, and it is more preferable to contain glass particles including P₂O₅—V₂O₅-based glass having a content of V₂O₅ of 0.1% by mass or more in an amount of 1 to 7% by mass.

### (Solvent and Resin)

The paste composition for an electrode of the first embodiment according to the present invention includes at least one kind of solvent and at least one kind of resin, thereby enabling adjustment of the liquid physical properties (for example, viscosity and surface tension) of the paste composition for an electrode of the present invention due to the application method selected when the paste composition is provided on the silicon substrate.

The solvent is not particularly limited. Examples thereof include hydrocarbon-based solvents such as hexane, cyclohexane, and toluene; chlorinated hydrocarbon-based solvents such as dichloroethylene, dichloroethane, and dichlorobenzene; cyclic ether-based solvents such as tetrahydrofuran, furan, tetrahydropyran, pyran, dioxane, 1,3-dioxolane, and trioxane; amide-based solvents such as N,N-dimethylformamide and N,N-dimethylacetamide; sulfoxide-based solvents such as dimethylsulfoxide, diethylsulfoxide; ketone-based solvents such as acetone, methyl ethyl ketone, diethyl ketone, and cyclohexanone; alcohol-based compounds such as ethanol, 2-propanol, 1-butanol, and diacetone alcohol; polyhydric alcohol ester-based solvents such as 2,2,4-trimethyl-1,3-pentanediol monoacetate, 2,2,4-trimethyl-1,3-pentanediol monopropionate, 2,2,4-trimethyl-1,3-pentanediol monobutyrate, 2,2,4-trimethyl-1,3-pentanediol monoisobutyrate, 2,2,4-triethyl-1,3-pentanediol monoacetate, ethylene glycol monobutyl ether acetate, and diethylene glycol monobutyl ether acetate; polyhydric alcohol ether-based solvents such as butyl cellosolve and diethylene glycol diethyl ether; terpene-based solvents such as α-terpinene, α-terpineol, myrcene, alloocimene, limonene, dipentene, α-pinene, β-pinene, terpineol, carvone, ocimene, and phellandrene, and mixtures thereof.

As the solvent in the present invention, from the viewpoint of applicability and printability when forming the paste composition for an electrode on a silicon substrate, at least one selected from polyhydric alcohol ester-based solvents, terpene-based solvents, and polyhydric alcohol ether-based solvents is preferred, and at least one selected from polyhydric alcohol ester-based solvents and terpene-based solvents is more preferred.

In the present invention, the solvents may be used singly or in combination of two or more kinds thereof.

Furthermore, as the resin, the usual resin used in the related art can be used without any limitation as long as it is thermally decomposable by sintering. Specific examples thereof include cellulose-based resins such as methyl cellulose, ethyl cellulose, carboxymethyl cellulose, and nitrocellulose; polyvinyl alcohols; polyvinyl pyrrolidones; acryl resins; vinyl acetate-acrylic ester copolymers; butyral resins such as polyvinyl butyral; alkyd resins such as phenol-modified alkyd resins and castor oil fatty acid-modified alkyd resins; epoxy resins; phenol resins; and rosin ester resins.

As the resin in the present invention, from the viewpoint of the loss upon sintering, at least one selected from cellulose-based resins and acryl resins is preferred, and at least one selected from cellulose-based resins is more preferred.

In the present invention, the resins may be used singly or in combination of two or more kinds thereof.

In the paste composition for an electrode of the first embodiment according to the present invention, the contents of the solvent and the resin can be appropriately selected in accordance with desired liquid physical properties or the kinds of the solvent and the resin to be used. For example, the total content of the solvent and the resin is preferably from 3 to 29.9% by mass, more preferably from 5 to 25% by mass, and even more preferably from 7 to 20% by mass, based on the total mass of the paste composition for an electrode of the first embodiment.

By setting the total content of the solvent and the resin in the above-described ranges, the providing suitability is improved when the paste composition for an electrode is provided on a silicon substrate, and thus, an electrode having a desired width and a desired height can be formed more easily.

### (Silver Particles)

The paste composition for an electrode of the first embodiment according to the present invention preferably further includes at least one kind of silver particle. By including the silver particles, the oxidation resistance is further improved, and the resistivity as the electrode is further reduced. In addition, when forming a photovoltaic cell, it enables to obtain the effect that the solder connectivity is improved.

Silver constituting the silver particles may contain other atoms which are inevitably incorporated. Examples of other atoms which are inevitably incorporated include Sb, Si, K, Na, Li, Ba, Sr, Ca, Mg, Be, Zn, Pb, Cd, Tl, V, Sn, Al, Zr, W, Mo, Ti, Co, Ni, and Au.

The particle diameter of the silver particle in the present invention is not particularly limited, and it is preferably from 0.4 to 10 μm, and from the viewpoint of promoting the sintering, it is more preferably from 0.4 to 2.0 μm in terms of a particle diameter when the cumulative mass is 50% (D50%).

When the particle diameter of the silver particles is 0.4 μm or more, the oxidation resistance is improved more effectively. Meanwhile, when the particle diameter is 10 μm or less, the contact area at which the metal particles such as silver particles and copper-containing particles contact each other in the electrode, increases, whereby resistivity is reduced more effectively.

In the paste composition for an electrode of the present invention, the relationship between the particle diameter (D50%) of the silver alloy particles and the particle diameter (D50%) of the silver particles is not particularly limited, and it is preferable that the particle diameter (D50%) of one of the silver alloy particles and the silver particles is smaller than the particle diameter (D50%) of the other of the silver alloy particles and the silver particles, and it is more preferable that the ratio of the particle diameter of the one of the silver alloy particles and the silver particles with respect to the particle diameter of the other of the silver alloy particles and the silver particles be from 1 to 10. Consequently, the resistivity of the electrode is reduced more effectively. It is thought that this is caused by increase in the contact area between the metal particles such as silver alloy particles and silver particles in the electrode.

Moreover, the content of the silver particles in the paste composition for an electrode of the first embodiment according to the present invention is preferably from 8.4 to 85.5% by mass, and more preferably from 8.9 to 80.1% by mass, based on the paste composition for an electrode, from the viewpoint of the oxidation resistance and the low resistivity of the electrode.

Further, in the present invention, from the viewpoint of the oxidation resistance and the low resistivity of the electrode, the content of the silver alloy particles when the total amounts of the silver alloy particles and the silver particles are taken as 100% by mass is preferably from 9 to 88% by mass, and more preferably from 17 to 77% by mass.

By setting the content of the silver alloy particles to 9% by mass or more, for example, in a case in which the glass particles include divanadium pentoxide, a reaction between silver and vanadium is suppressed, which results in a reduction of the volume resistance of the electrode. Also, when a silicon substrate for forming an electrode is treated by an aqueous hydrofluoric acid solution for the purpose of improving the energy conversion efficiency of a photovoltaic cell, the above content of the silver alloy leads to improvement in the resistance of the electrode material against the aqueous hydrofluoric acid solution (this property means that the electrode material does not peel from the silicon substrate due to the aqueous hydrofluoric acid solution).

Further, by setting the content of the silver alloy particles to 88% by mass or less, the contact resistance of the electrode is further reduced.

Moreover, in the paste composition for an electrode of the first embodiment according to the present invention, from the viewpoint of the oxidation resistance and the low resistivity of the electrode, it is preferable that the total content of the silver alloy particles and the silver particles be from 70 to 94% by mass, the content of the glass particles be from 0.1 to 10% by mass, and the total content of the solvent and the resin be from 3 to 29.9% by mass, and it is more preferable that the total content of the silver alloy particles and the silver particles be from 74 to 88% by mass, the content of the glass particles be from 1 to 7% by mass, and the total content of the solvent and the resin be from 7 to 20% by mass.

### (Other Components)

Furthermore, the paste composition for an electrode of the first embodiment according to the present invention can include, in addition to the above-described components, other components generally used in the related art, if necessary. Examples of other components include a plasticizer, a dispersant, a surfactant, an inorganic binder, a metal oxide, a ceramic, and an organic metal compound.

### (Method for Forming Paste Composition for Electrode)

The method for forming the paste composition for an electrode of the first embodiment according to the present invention is not particularly limited. The paste composition can be prepared by dispersing or mixing silver alloy particles, glass particles, a solvent, a resin, and additionally silver particles and the like if necessary, by a typically used dispersing or mixing method.

### (Method for Producing Electrode Using Paste Composition for Electrode)

As for the method for preparing an electrode using the paste composition for an electrode according to the present invention, the paste composition for an electrode can be provided in a region in which the electrode is formed, dried, and then sintered to form the electrode in a desired region. By using the paste composition for an electrode, an electrode having a low resistivity can be formed even with a sintering treatment in the presence of oxygen (for example, in the atmosphere).

Specifically, for example, when an electrode for a photovoltaic cell is formed using the paste composition for an electrode, the paste composition for an electrode can be provided to a silicon substrate to a desired shape, dried, and then sintered to form an electrode for a photovoltaic cell having a low resistivity in a desired shape. Further, by using the paste composition for an electrode, an electrode having a low resistivity can be formed even with a sintering treatment in the presence of oxygen (for example, in the atmosphere).

Examples of the method for providing the paste composition for an electrode on a silicon substrate include screen printing, an ink-jet method, and a dispenser method, and from the viewpoint of the productivity, application by screen printing is preferred.

When the paste composition for an electrode of the first embodiment according to the present invention is applied by screen printing, it is preferable that the viscosity be in the range of from 80 to 1000 Pa·s. Further, the viscosity of the paste composition for an electrode is measured using a Brookfield HBT viscometer at 25° C.

The amount of the paste composition for an electrode to be provided can be appropriately selected according to the size of the electrode formed. For example, the amount of the paste composition for an electrode to be provided can be from 2 to 10 g/m², and preferably from 4 to 8 g/m².

Moreover, as heat treatment conditions (sintering conditions) when forming an electrode using the paste composition for an electrode of the first embodiment according to the present invention, the heat treatment conditions generally used in the related art can be applied, and in general, the heat treatment temperature (sintering temperature) is from 800 to 900° C.

In addition, the heat treatment time can be appropriately selected according to the heat treatment temperatures or the like, and it may be, for example, from 1 second to 20 seconds.

### <Paste Composition for Electrode of Second Embodiment>

The paste composition for an electrode of the second embodiment according to the present invention includes copper particles, silver or silver alloy particles, glass particles containing P₂O₅ and V₂O₅, a resin, and a solvent, in which the content of the copper particles with respect to the silver or silver alloy particles is from 9% by mass to 88% by mass.

As described above, when the lead-free glass particles containing P₂O₅ and V₂O₅ are used in the paste composition for an electrode, V₂O₅ (divanadium pentoxide) contained therein reacts with silver contained as a conductive metal powder to form silver vanadate, and thus, the resistivity of the electrode formed increases. Therefore, the use of metals other than silver as a conductive metal powder has been investigated and, as a result, it is clear that use of copper (Cu) in combination with silver (Ag) at specific ratios is effective for the formation of an electrode, resulting in inhibition of an increase in the resistivity.

Particularly, the paste composition for an electrode, in which a content of the copper particles with respect to the silver or the silver alloy particles is from 9% by mass to 88% by mass, enables inhibition of an increase in the resistivity of the electrode. On the contrary, when the content of the copper particles with respect to the silver or the silver alloy particles is less than 9% by mass, it is difficult to inhibit a rise in resistivity which is caused by silver vanadate produced by the reaction of V₂O₅ (divanadium pentoxide) with Ag (silver). When the content is more than 88% by mass, the resistivity of the electrode becomes higher due to copper oxide produced by oxidation of copper.

Here, a phenomenon that the oxidation of copper is inhibited by the use of the copper particles in combination with the silver particles will be described.

Generally, in a temperature region of from 600° C. to 900° C., which is an electrode-forming temperature region, a small amount of silver is solved into copper, and a small amount of copper is solved into silver, whereby a layer of the copper-silver solid solution (solid solution region) is formed at an interface between copper and silver. When a mixture of the copper-containing particles and the silver particles is heated at a high temperature, and then slowly cooled to room temperature, it is thought that the solid solution region is not generated. However, when forming an electrode, since cooling is carried out for a few seconds from a high temperature region to a normal temperature, it is thought that the layer of the solid solution at a high temperature covers the surface of the silver particles and the copper-containing particles as a non-equilibrium solid solution phase or as an eutectic structure of copper and silver. It is assumed that such a copper-silver solid solution layer contributes to the oxidation resistance of the copper-containing particles at an electrode-forming temperature.

Further, the copper-silver solid solution layer starts to be formed at a temperature of from 300° C. to 500° C. or higher. Accordingly, it is thought that the oxidation resistance of the copper-containing particles can be improved more effectively by using the silver particles in combination with the copper-containing particles whose peak temperature of the exothermic peak having a maximum area is 280° C. or higher, measured in the simultaneous ThermoGravimetry/Differential Thermal Analysis, whereby the resistivity of the electrode to be formed is further reduced.

As explained above, when the content of the copper particles with respect to the silver or the silver alloy particles is more than 88% by mass, the amount of Ag particles is insufficient, and thus, a Cu—Ag solid solution layer cannot sufficiently fill the intervals between the particles, and noticeable oxidation of Cu occurs.

Hereinafter, each of the components constituting the paste composition for an electrode of the second embodiment will be described in detail.

### (Copper Particles)

The copper particles in the present invention may be constructed by pure copper, by substantially consisting of copper, including other atoms in an amount which dose not impair the effect of the invention. Also the copper particles may be constructed by including copper and other components for imparting copper with oxidation resistance.

Examples of other atoms in the metal particles substantially consisting of copper include Sb, Si, K, Na, Li, Ba, Sr, Ca, Mg, Be, Zn, Pb, Cd, Tl, V, Sn, Al, Zr, W, Mo, Ti, Co, Ni, and Au. Among these, from the viewpoint of adjustment of the characteristics such as the oxidation resistance and a melting point, Al is preferably included.

Further the content of other atoms contained in the copper particle can be, for example, 3% by mass or less in the copper particle, and from the viewpoint of the oxidation resistance and the low resistivity, it is preferably 1% by mass or less.

The particle diameter of the copper particles is not particularly limited, and it is preferably from 0.4 to 10 μm, and more preferably from 1 to 7 μm in terms of a particle diameter when the cumulative mass is 50% (hereinafter abbreviated as “D50%” in some cases). By setting the particle diameter to 0.4 μm or more, the oxidation resistance is improved more effectively. Further, by setting the particle diameter to 10 μm or less, the contact area at which the copper particles contact each other in the electrode increases, whereby the resistivity is reduced more effectively. The particle diameter of the copper particle is measured by means of a MICROTRAC particle size distribution analyzer (MT3300 type, manufactured by Nikkiso Co., Ltd.).

In addition, the shape of the copper particle is not particularly limited, and it may be any one of an approximately spherical shape, a flat shape, a block shape, a plate shape, a scale-like shape, and the like. From the viewpoint of oxidation resistance and low resistivity, it is preferably an approximately spherical shape, a flat shape, or a plate shape.

The total content of the copper particles, and the silver particles and the silver alloy particles (silver-containing particles) can be, for example, from 70 to 94% by mass, preferably from 72 to 90% by mass from the viewpoint of oxidation resistance and low resistivity, and more preferably from 74 to 88% by mass, in the paste composition for an electrode of the second embodiment according to the present invention.

By setting the total content of the copper particles and the silver-containing particles to 70% by mass or more, a suitable viscosity upon providing the paste composition for an electrode can be easily attained. Also, by setting the total content of the copper particles and the silver-containing particles to 94% by mass or less, the occurrence of abrasion upon providing the paste composition for an electrode can be inhibited more effectively.

Further, in the present invention, conductive particles other than the copper particles, the silver particles, and the silver alloy particles may be used in combination therewith.

### (Silver Particles or Silver Alloy Particles)

The paste composition for an electrode of the present invention further includes at least one of silver particles or silver alloy particles (hereinafter referred to as the “silver-containing particles” in some cases).

The silver particles and the silver alloy particles may be pure silver, metal particles substantially consisting of only silver, also including other atoms which are inevitably incorporated, or silver alloy particles.

Examples of other atoms which are inevitably incorporated into the metal particles substantially consisting of only silver include Sb, Si, K, Na, Li, Ba, Sr, Ca, Mg, Be, Zn, Pb, Cd, Tl, V, Sn, Al, Zr, W, Mo, Ti, Co, Ni, and Au.

As the silver alloy particles, the silver alloy particles described in the paste composition for an electrode of the first embodiment can also be applied herein, in addition to the suitable ranges thereof.

The particle diameter (D50%), when the cumulative mass is 50%, of the silver-containing particle is preferably from 0.4 to 10 μm, and more preferably from 1 to 5 μm.

By setting the particle diameter to 0.4 μm or more, the oxidation resistance is improved more effectively. Further, by setting the particle diameter to 10 μm or less, the contact area, which the metal particles such as silver-containing particles and copper particles contact each other in the electrode, is widened, whereby the resistivity is reduced more effectively.

In the paste composition for an electrode of the second embodiment according to the present invention, the content of the copper particles with respect to the silver or silver alloy particles is preferably from 9 to 88% by mass, and more preferably from 17 to 77% by mass.

### (Glass Particles Containing P₂O₅ and V₂O₅)

The paste composition for an electrode of the second embodiment according to the present invention includes at least one kind of glass particle containing P₂O₅ and V₂O₅ (hereinafter referred to as the “P₂O₅—V₂O₅-based glass particle” in some cases), in consideration of an effect on the environment. By incorporating glass particles in the paste composition for an electrode, a silicon nitride film which is an anti-reflection film is removed by a so-called fire-through at an electrode-forming temperature, and an ohmic contact between the electrode metal and the silicon substrate is formed.

Since the glass particle according to the present invention contains diphosphorus pentoxide, reduction in the contact resistivity is promoted. Further, since it also contains divanadium pentoxide in addition to diphosphorus pentoxide, the softening point of the glass is lowered, and thus the oxidation resistance is further improved and the resistivity of the electrode is further reduced.

In the present invention, the addition of copper particle leads to inhibit to raise resistivity, while the raising resistivity is caused by silver vanadate produced by the reaction of V₂O₅ (divanadium pentoxide) with Ag (silver). Therefore, the content of divanadium pentoxide in the P₂O₅—V₂O₅-based glass particles is not particularly limited. The content of divanadium pentoxide in the P₂O₅—V₂O₅-based glass particles is preferably from 1 to 70% by mass.

Moreover, the P₂O₅—V₂O₅ glass particles may further contain other components, if necessary. Examples of other components include barium oxide, manganese dioxide, sodium oxide, potassium oxide, zinc oxide, zirconium dioxide, tungsten trioxide, tellurium oxide, antimony oxide, and iron oxide. By further including other components, silicon dioxide derived from the silicon nitride can be more efficiently incorporated, and the softening or melting temperature can be further reduced. In addition, the reaction with the copper particles, or the silver particles or silver alloy particles can be inhibited.

The content of the P₂O₅—V₂O₅-based glass particles is preferably 0.1 to 10% by mass, more preferably 0.5 to 8% by mass, and even more preferably 1 to 7% by mass, based on the total mass of the paste composition for an electrode of the second embodiment. By including the P₂O₅—V₂O₅-based glass particles at a content in this range, the oxidation resistance, the low resistivity of the electrode, and the low contact resistance are attained more effectively.

### (Resin and Solvent)

The paste composition for an electrode of the second embodiment according to the present invention includes at least one kind of resin and at least one kind of solvent, thereby enabling adjustment of the liquid physical properties (for example, viscosity and surface tension) of the paste composition for an electrode of the present invention due to the application method selected when the paste composition is applied on the silicon substrate.

The solvent and the resin which can be applied in the paste composition for an electrode of the second embodiment are the same as the solvent and the resin described for the paste composition for an electrode of the first embodiment, in addition to the suitable ranges and contents thereof. Hence, the descriptions thereof are omitted here.

Furthermore, in the paste composition for an electrode of the present invention, from the viewpoint of the oxidation resistance and the low resistivity of the electrode, it is preferable that the total content of the copper particles and the silver-containing particles be from 70 to 94% by mass, the content of the copper particles with respect to the silver-containing particles be from 9% by mass to 88% by mass, the content of the P₂O₅—V₂O₅-based glass particles be from 0.1 to 10% by mass, and the total content of the solvent and the resin be from 3 to 29.9% by mass, and it is more preferable the total content of the copper particles and the silver-containing particles be from 74 to 88% by mass, the content of the copper particles with respect to the silver-containing particles be from 17% by mass to 77% by mass, the content of the P₂O₅—V₂O₅-based glass particles be from 1 to 7% by mass, and the total content of the solvent and the resin be from 7 to 20% by mass.

### (Other Components)

Furthermore, the paste composition for an electrode of the second embodiment according to the present invention may include, in addition to the above-described components, other components generally used in the related art, if necessary. Examples of other components include a plasticizer, a dispersant, a surfactant, an inorganic binder, a metal oxide, a ceramic, and an organic metal compound.

### (Method for Preparing Paste Composition for Electrode)

The method for preparing the paste composition for an electrode of the second embodiment according to the present invention is not particularly limited. The paste composition can be prepared by dispersing and mixing copper particles, silver particles or silver alloy particles, glass particles, a solvent, a resin, silver particles to be added, if necessary, and the like, by a typically used dispersing or mixing method.

### (Method for Producing Electrode Using Paste Composition for Electrode)

As for the method for preparing an electrode using the second paste composition for an electrode according to the present invention, the paste composition for an electrode can be provided in a region in which the electrode is formed, dried, and then sintered to form the electrode in a desired region. By using the paste composition for an electrode, an electrode having a low resistivity can be formed even with a sintering treatment in the presence of oxygen (for example, in the atmosphere).

Specifically, for example, when an electrode for a photovoltaic cell is formed using the paste composition for an electrode, the paste composition for an electrode can be provided to a silicon substrate to a desired shape, dried, and then sintered to form an electrode for a photovoltaic cell having a low resistivity in a desired shape. Further, by using the paste composition for an electrode, an electrode having a low resistivity can be formed even with a sintering treatment in the presence of oxygen (for example, in the atmosphere).

When the paste composition for an electrode of the second embodiment according to the present invention is applied by screen printing, it is preferable that the viscosity be in the range of from 80 to 1000 Pa·s. The viscosity of the paste composition for an electrode is measured using a Brookfield HBT viscometer at 25° C.

The amount of the paste composition for an electrode to be provided can be appropriately selected according to the size of the electrode formed. For example, the amount of the paste composition for an electrode to be provided can be from 2 to 10 g/m², and preferably from 4 to 8 g/m².

Moreover, as heat treatment conditions (sintering conditions) when forming an electrode using the paste composition for an electrode of the second embodiment according to the present invention, heat treatment conditions generally used in the related art can be applied.

Generally, the heat treatment temperature (sintering temperature) is from 800 to 900° C., but when using the paste composition for an electrode of the present invention, a heat treatment condition at a lower temperature can be applied. For example, even if a heat treatment temperature is from 600 to 850° C., an electrode having good characteristics can be formed.

In addition, the heat treatment time can be appropriately selected according to the heat treatment temperatures, and it may be, for example, from 1 second to 20 seconds.

### <Photovoltaic Cell>

The photovoltaic cell of the present invention has an electrode formed by sintering the paste composition for an electrode provided on the silicon substrate in the presence of oxygen. As a result, a photovoltaic cell having good characteristics can be obtained, and the productivity of the photovoltaic cell is excellent.

Hereinbelow, specific examples of the photovoltaic cell of the present invention will be described with reference to the drawings, but the present invention is not limited thereto.

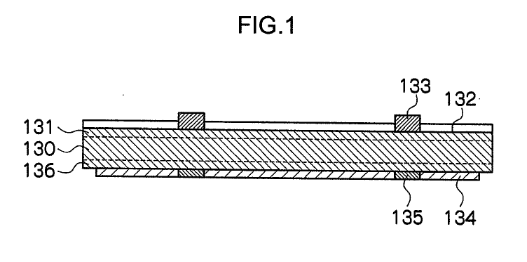

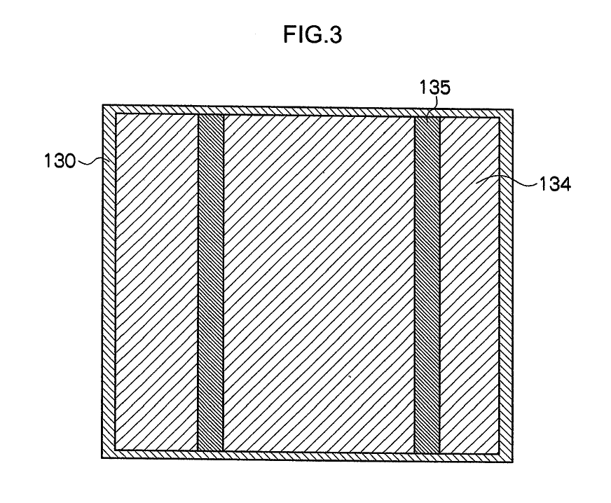

A cross-sectional view, and schematic views of the light-receiving surface and the back surface of one example of the representative photovoltaic cell elements are shown in FIGS. 1, 2 and 3, respectively.

Typically, monocrystalline or polycrystalline Si, or the like is used for a semiconductor substrate 130 of a photovoltaic cell element. This semiconductor substrate 130 contains boron and the like to constitute a p-type semiconductor. Unevenness (texture, not shown) is formed on the light-receiving surface side by etching so as to inhibit the reflection of sunlight. Phosphorous and the like are doped on the light-receiving surface side to provide a diffusion layer 131 of an n-type semiconductor with a thickness on the order of submicrons, and a p/n junction is formed at the boundary with the p-type bulk portion. Also, on the light-receiving surface side, an anti-reflection layer 132 such as silicon nitride with a film thickness of around 100 nm is provided on the diffusion layer 131 by a vapor deposition method.

Next, a light-receiving surface electrode 133 provided at the light-receiving surface side, a current collection electrode 134 formed at the back surface, and an output extraction electrode 135 will be described. The light-receiving surface electrode 133 and the output extraction electrode 135 are formed from the paste composition for an electrode. Further, the current collection electrode 134 is formed from the aluminum electrode paste composition including glass powders. These electrodes are formed by applying the paste composition for a desired pattern by screen printing or the like, drying, and then sintering at about 600 to 850° C. in an atmosphere.

Here, on the light-receiving surface side, the glass particles included in the paste composition for an electrode to form the light-receiving surface electrode 133 undergo a reaction with the anti-reflection layer 132 (fire-through), thereby electrically connecting (ohmic contact) the light-receiving surface electrode 133 and the diffusion layer 131.

In the present invention, due to using the paste composition for an electrode to form the light-receiving surface electrode 133 including copper as a conductive material, the oxidation of copper is inhibited, whereby the light-receiving surface electrode 133 having a low resistivity is produced at high productivity.

Further, on the back surface side, upon sintering, aluminum which is included in the aluminum electrode paste composition for forming the current collection electrode 134 is diffused on and into the back surface of the semiconductor substrate 130 to form an electrode component diffusion layer 136, and as a result, ohmic contact is formed among the semiconductor substrate 130, the current collection electrode 134, and the output extraction electrode 135.

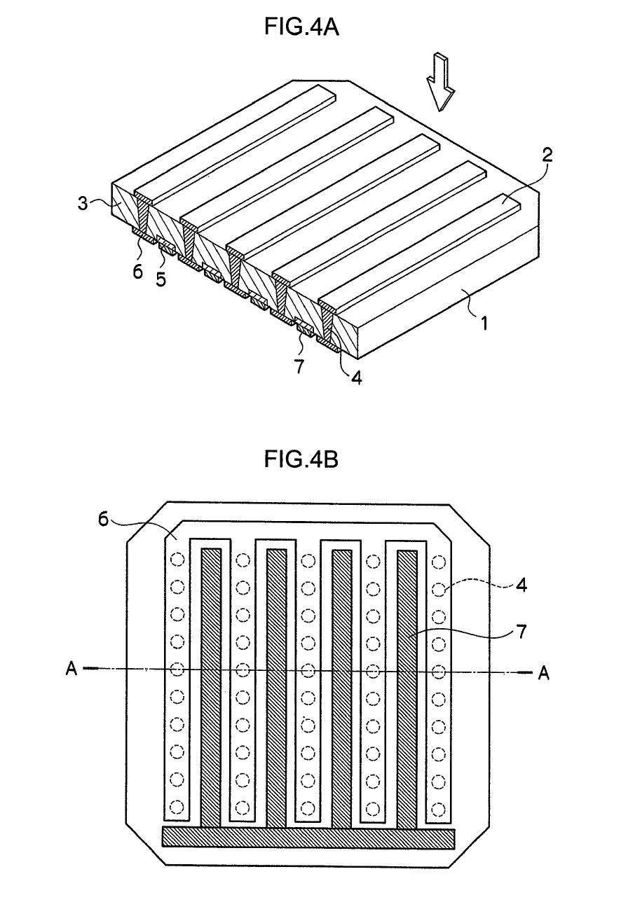

In FIG. 4, the perspective view (a) of the light-receiving surface and the AA cross-section structure, and the plane view (b) of the back surface side electrode structure in one example of the photovoltaic cell element are shown as another embodiment according to the present invention.

As shown in FIG. 4, in a cell wafer 1 consisting of a silicon substrate of a p-type semiconductor, a through-hole which passes through both sides of the light-receiving surface side and the back surface side is formed by laser drilling, etching, or the like. Further, a texture (not shown) for improving the efficiency of incident light is formed on the light-receiving surface side. Also, the light-receiving surface side has an n-type semiconductor layer 3 formed by n-type diffusion treatment, and an anti-reflection film (not shown) formed on the n-type semiconductor layer 3. These are prepared by the same processes as for a conventional crystal Si-type photovoltaic cell.

Next, the paste composition for an electrode of the present invention is filled in the inside of the through-hole previously formed by a printing method or an ink-jet method, and also, the paste composition for an electrode of the present invention is similarly printed in the grid shape on the light-receiving surface side, thereby forming a composition layer which forms the through-hole electrode 4 and the grid electrode 2 for current collection.

Here, regarding the paste used for filling and printing, although it is preferable to use the most suitable paste for each process from the point of view of properties such as viscosity, one paste of the same composition may be used for filling and printing at the same time.

On the other hand, a high-concentration doped layer 5 is formed on the opposite side of the light-receiving surface (back surface side) so as to prevent the carrier recombination. Here, as an impurity element for forming the high-concentration doped layer 5, boron (B) or aluminum (Al) is used, and a p⁺ layer is formed. This high-concentration doped layer 5 may be formed by carrying out a thermal diffusion treatment using, for example, B as a diffusion source in the process of preparing a cell before forming the anti-reflection film, or when using Al, it may also be formed by printing an Al paste on the opposite surface side in the printing step.

Thereafter, the paste composition for an electrode is printed on the side of an anti-reflection film and is also filled in the inside of the through-hole, which is formed on the light-receiving surface side, and then is sintered at 650 to 850° C., whereby the paste composition can attain ohmic contact with the n-type layer as an under layer by a fire-through effect.

Furthermore, as shown in the plane view of FIG. 4(b), the paste composition for an electrode according to the present invention is printed in stripe shapes on each of the n side and the p side, and sintered, and thus, the back surface electrodes 6 and 7 are formed on the opposite surface side.

In the present invention, the through-hole electrode 4, the grid electrode 2 for current collection, the back surface electrode 6, and the back surface electrode 7 are formed using the paste composition for an electrode. As a result, despite including copper as a conductive metal, the oxidation of copper is inhibited, whereby the through-hole electrode 4 having a low resistivity, and the grid electrode 2 for current collection, the back surface electrode 6 and the back surface electrode 7 are formed with high productivity.

Moreover, the paste composition for an electrode of the present invention is not restricted to the applications of photovoltaic cell electrodes described above, and can also be appropriately used in applications such as, for example, electrode wirings and shield wirings of plasma displays, ceramic condensers, antenna circuits, various sensor circuits, and heat dissipation materials of semiconductor devices.

### EXAMPLES

Hereinafter, the present invention will be described in detail with reference to Examples, but the present invention is not limited to these Examples. Further, unless otherwise specified, “parts” and “%” are based on mass.

### Example 1

### (a) Preparation of Silver Alloy Particles

A silver alloy containing 63% of Ag, 35% of Cu, and 2% of P was prepared, dissolved, made into powders by a water atomization method, then dried, and classified. The classified powders were blended and subjected to deoxidation/dehydration treatments to prepare silver alloy particles. Further, the particle diameter (D50%) of the silver alloy particle was 1.5 μm.

### (b) Preparation of Silver Particles

As the silver particle, three kinds of commercially available reagents (manufactured by Mitsui Mining & Smelting Co., Ltd.) having particle diameters (D50%) of 0.4 μm, 1.1 μm, and 1.7 μm were prepared.

### (c) Preparation of Glass Particles

As the glass particles, two kinds of the glass particles were prepared.

The composition of Glass 1 (P19) included 32 parts by weight of vanadium oxide (V₂O₅), 26 parts by weight of phosphorous oxide (P₂O₅), 10 parts by weight of barium oxide (BaO), 8 parts by weight of manganese oxide (MnO₂), 1 part by weight of sodium oxide (Na₂O), 3 parts by weight of potassium oxide (K₂O), 10 parts by weight of zinc oxide (ZnO), and 10 parts by weight of tungsten oxide (WO₃). The glass had a softening point of 447° C. and a crystallization temperature of 600° C. or higher.

The composition of Glass 2 (AY1) included 45 parts of vanadium oxide (V₂O₅), 24.2 parts of phosphorous oxide (P₂O₅), 20.8 parts of barium oxide (BaO), 5 parts of antimony oxide (Sb₂O₃), and 5 parts of tungsten oxide (WO₃), and had a particle diameter (D50%) of 1.7 μm. Further, the glass had a softening point of 492° C. and a crystallization temperature of higher than 600° C.

### (d) Preparation of Paste Composition for Electrode

The copper powders and the Ag powder were weighed and mixed to the blending ratios shown in Table 1, and further, the silver alloy particles, the silver particles, the glass particles, a solvent, and a resin were measured to the blending ratios shown in Table 1, and mixed by stirring in a mortar made of agate for 20 minutes, thereby preparing a paste composition 1 for an electrode.

Further, diethylene glycol monobutyl ether acetate (hereinafter referred to as BCA) was used as the solvent and ethyl cellulose (hereinafter referred to as EC) was used as the resin, and then BCA containing 4% of EC was prepared, followed by adjusted for the amount of the solvent so as to render the viscosity of the paste to 80 to 200 Pa·s which is suitable for screen printing.

### (d) Preparation of Photovoltaic Cell

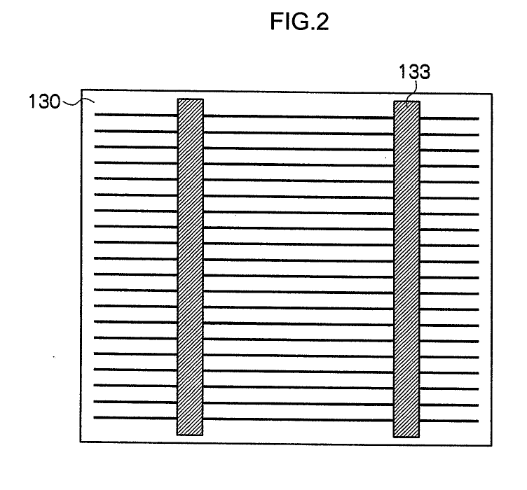

A p-type semiconductor substrate having a film thickness of 190 μm, in which an n-type semiconductor layer, a texture, and an anti-reflection film (silicon nitride film) were formed on the light-receiving surface, was prepared, and cut to a size of 125 mm×125 mm. The paste composition 1 for an electrode obtained above was printed on the light-receiving surface for an electrode pattern as shown in FIG. 2, using a screen printing method. The pattern of the electrode was constituted with finger lines with a 150 μm width and bus bars with a 1.1 mm width, and the printing conditions (a mesh of a screen plate, a printing speed, a printing pressure) were appropriately adjusted so as to give a film thickness after sintering of 20 μm. The resultant was put into an oven heated at 150° C. for 15 minutes, and the solvent was removed by vaporization.

Subsequently, an aluminum electrode paste was similarly printed on the entire surface of the back surface by screen printing. The printing conditions were appropriately adjusted so as to give a film thickness after sintering of 40 μm. The resultant was put into an oven heated at 150° C. for 15 minutes, and the solvent was removed by vaporization.

Then, a heating treatment (sintering) was carried out at 850° C. for two seconds under an air atmosphere in an infrared rapid heating furnace to prepare a photovoltaic cell 1 having a desired electrode formed therein.

### Examples 2 to 13

In the same manner as in Example 1, except that the blending ratios of the silver alloy particles and the silver particles, the particle diameter (D50%) of the silver particles, and the type and content of the glass particles were changed as shown in Table 1 in Example 1, photovoltaic cells 2 to 13 ware prepared.

### Comparative Example 1

In the same manner as in Example 1, except that the paste composition for an electrode was prepared while not incorporating the silver alloy particles in Example 1, photovoltaic cell 1 was prepared.

<Evaluation of Photovoltaic cell Element>

The cells of the photovoltaic cell elements prepared were evaluated with a combination of WXS-155 S-10 (manufactured by Wacom-Electric Co., Ltd.) as artificial sunlight and a measurement device of 1-V CURVE TRACER MP-160 (manufactured by EKO INSTRUMENT CO., LTD.) as a current-voltage (I-V) evaluation and measurement device. The results of the power generation performances as the photovoltaic cells formed from the pastes prepared in Examples and Comparative Examples are shown together in Table 1.

The respective measured values for the power generation performances as the photovoltaic cells are shown in Table 1 in terms of a relative value when the value measured in Comparative Example 1 was taken as 100.0. Further, Eff (conversion efficiency), FF (fill factor), Voc (open voltage), and Jsc (short circuit current) indicating the power generation performances as a photovoltaic cell were obtained by carrying out the measurement method in accordance with each of JIS-C-8912, JIS-C-8913, and JIS-C-8914.

TABLE 1

| | | | | | | | | Power Generation Performance as | | | |
|---|---|---|---|---|---|---|---|---|---|---|---|
| | | | | | | | | Photovoltaic Cell | | | |
| | Silver Alloy | | | | | | | | | | Jsc |
| | Particles | | Silver Particles | | | | 4% EC- | Eff | FF | Voc | (relative |
| | Particle | | Particle | | | | containing | (relative | (relative | (relative | value) |
| | diameter | | diameter | | Glass Particles | | BCA | value) | value) | value) | Short |
| | (D50%) | Content | (D50%) | Content | | Content | solution | Conversion | Fill | Open | circuit |
| Example | (μm) | (parts) | (μm) | (parts) | Type | (parts) | (parts) | efficiency | factor | voltage | current |
| 1 | 1.5 | 55 | 1.1 | 45 | P19 | 2 | 15 | 100.2 | 100.5 | 99.7 | 99.7 |
| 2 | 1.5 | 60 | 1.1 | 40 | P19 | 2 | 15 | 100.0 | 100.2 | 99.6 | 99.6 |
| 3 | 1.5 | 65 | 1.1 | 35 | P19 | 2 | 15 | 99.8 | 100.1 | 98.5 | 99.6 |
| 4 | 1.5 | 70 | 1.1 | 30 | P19 | 2 | 15 | 99.6 | 99.8 | 98.3 | 99.5 |
| 5 | 1.5 | 75 | 1.1 | 25 | P19 | 2 | 15 | 99.6 | 99.7 | 99.3 | 99.4 |
| 6 | 1.5 | 35 | 1.1 | 65 | P19 | 2 | 15 | 103.0 | 102.4 | 100.3 | 104.2 |
| 7 | 1.5 | 45 | 1.1 | 55 | P19 | 2 | 15 | 102.3 | 102.3 | 100.0 | 103.1 |
| 8 | 1.5 | 50 | 1.1 | 50 | P19 | 2 | 15 | 101.5 | 101.2 | 99.8 | 99.5 |
| 9 | 1.5 | 55 | 1.1 | 45 | P19 | 1 | 15 | 103.5 | 102.3 | 100.4 | 100.0 |
| 10 | 1.5 | 55 | 1.1 | 45 | P19 | 4 | 15 | 99.4 | 99.3 | 99.4 | 99.2 |
| 11 | 1.5 | 55 | 1.7 | 45 | AY1 | 2 | 15 | 97.8 | 93.2 | 98.5 | 95.0 |
| 12 | 1.5 | 45 | 1.7 | 55 | AY1 | 2 | 15 | 98.6 | 99.3 | 98.7 | 98.0 |
| 13 | 1.5 | 55 | 0.4 | 45 | P19 | 2 | 15 | 104.3 | 104.6 | 100.4 | 104.0 |
| Comparative | — | 0 | 1.1 | 100 | P19 | 2 | 15 | 100.0 | 100.0 | 100.0 | 100.0 |
| Example 1 | | | | | | | | | | | |

### (Results and Review)

As shown by the results in Table 1, the paste compositions for an electrode of Examples 1 to 13, including the silver alloys, reduced the amount of silver to be used, and further, did not remarkably deteriorate the above-described electrical characteristics.

In the paste compositions for an electrode of Examples 1 to 13, a total content of the silver alloy particles and the silver particles was from 70% by mass to 94% by mass, a content of the glass particles was from 0.1% by mass to 10% by mass, and a total content of the solvent and the resin was from 3% by mass to 30% by mass, and excellent electrical characteristics as described above could be obtained. When reviewing the reasons for the above, it is believed that the contact resistance between the electrode and the substrate is lowered due to the increase in the FF value. This may be caused by the inhibition of the reaction of V₂O₅ with Ag due to the presence of the silver alloy particles, resulting in the reduction in the contact resistance.

From the above description, it can be seen that the paste compositions for an electrode of the present invention of Examples 1 to 13 are preferable for formation of an electrode of a cell of a photovoltaic cell. Further, the paste compositions can reduce the amount of expensive silver to be used, and contribute to a reduction in the cost.

Further, since the glass particles used in the paste compositions for an electrode of Examples 1 to 13 do not contain lead components, they can lessen an effect on the environment.

Moreover, the silver particles having a particle diameter of 1.1 μm were superior in electrical characteristics than the silver particles having a particle diameter of 0.4 μm. It is assumed that this is why reduction of the size of the silver particles leads to promotion of sintering resulting in reduction in the volume resistivity.

In addition, from the results of Examples 1 and 11, it is apparent that a lower softening point of the glass particles contributes to excellent electrical characteristics, and the lower softening point of the glass particles is preferably 450° C. or lower.

### Example 14

A photovoltaic cell 14 having the structure as shown in FIG. 4 was prepared using the paste composition 9 for an electrode, which had been obtained above. In this case, the heating treatment was carried out at 750° C. for 10 seconds.

The photovoltaic cell obtained was evaluated in the same manner as above, and as a result, it could be seen that the excellent characteristics are exhibited.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

1. A paste composition for an electrode, the paste composition comprising:
silver alloy particles;
glass particles;
a resin; and
a solvent.

2. The paste composition for an electrode according to claim 1, wherein the glass particles comprise P₂O₅ and V₂O₅.

3. The paste composition for an electrode according to claim 1, further comprising silver particles.

4. The paste composition for an electrode according to claim 1, wherein:
a total content of the silver alloy particles and the silver particles is from 70% by mass to 94% by mass;
a content of the glass particles is from 0.1% by mass to 10% by mass; and
a total content of the solvent and the resin is from 3% by mass to 30% by mass.

5. A paste composition for an electrode, the paste composition comprising:
copper particles;
silver or silver alloy particles;
glass particles including P₂O₅ and V₂O₅;
a resin; and
a solvent,
wherein a content of the copper particles with respect to the silver or silver alloy particles is from 9% by mass to 88% by mass.

6. A photovoltaic cell having an electrode, wherein the electrode is formed by applying the paste composition for an electrode according to claim 1 to a silicon substrate, and sintering the paste composition.

7. The paste composition for an electrode according to claim 2, further comprising silver particles.

8. The paste composition for an electrode according to claim 7, wherein:
a total content of the silver alloy particles and the silver particles is from 70% by mass to 94% by mass;
a content of the glass particles is from 0.1% by mass to 10% by mass; and
a total content of the solvent and the resin is from 3% by mass to 30% by mass.

9. The paste composition for an electrode according to claim 2, wherein:
a total content of the silver alloy particles and the silver particles is from 70% by mass to 94% by mass;
a content of the glass particles is from 0.1% by mass to 10% by mass; and
a total content of the solvent and the resin is from 3% by mass to 30% by mass.

10. The paste composition for an electrode according to claim 3, wherein:
a total content of the silver alloy particles and the silver particles is from 70% by mass to 94% by mass;
a content of the glass particles is from 0.1% by mass to 10% by mass; and
a total content of the solvent and the resin is from 3% by mass to 30% by mass.

11. A photovoltaic cell having an electrode, wherein the electrode is formed by applying the paste composition for an electrode according to claim 2 to a silicon substrate, and sintering the paste composition.

12. A photovoltaic cell having an electrode, wherein the electrode is formed by applying the paste composition for an electrode according to claim 3 to a silicon substrate, and sintering the paste composition.

13. A photovoltaic cell having an electrode, wherein the electrode is formed by applying the paste composition for an electrode according to claim 4 to a silicon substrate, and sintering the paste composition.

14. A photovoltaic cell having an electrode, wherein the electrode is formed by applying the paste composition for an electrode according to claim 7 to a silicon substrate, and sintering the paste composition.

15. A photovoltaic cell having an electrode, wherein the electrode is formed by applying the paste composition for an electrode according to claim 8 to a silicon substrate, and sintering the paste composition.

16. A photovoltaic cell having an electrode, wherein the electrode is formed by applying the paste composition for an electrode according to claim 9 to a silicon substrate, and sintering the paste composition.

17. A photovoltaic cell having an electrode, wherein the electrode is formed by applying the paste composition for an electrode according to claim 10 to a silicon substrate, and sintering the paste composition.
